(19) United States
(12) Patent Application Publication
(10) Pub. No.: US 2025/0084562 A1
(43) Pub. Date: Mar. 13, 2025

(54) POROUS SILICON STRUCTURE MANUFACTURING METHOD

(71) Applicant: Taiwan-Asia Semiconductor Corporation, Hsinchu City (TW)

(72) Inventor: Hou-Jun Wu, Hsinchu City (TW)

(21) Appl. No.: 18/765,914

(22) Filed: Jul. 8, 2024

(30) Foreign Application Priority Data
Sep. 13, 2023 (TW) 112134972

(51) Int. Cl. C30B 33/10; C30B 29/06

(52) U.S. Cl. CPC C30B 33/10; C30B 29/06

(57) ABSTRACT

A porous silicon structure manufacturing method is provided. The porous silicon structure manufacturing method involves forming an epitaxial layer on a substrate and forming a protective layer on the epitaxial layer. The protective layer includes an opening region. An electrochemical etching is performed within the opening region to create a porous silicon structure on the epitaxial layer. After removing the protective layer, a wafer with a porous silicon structure is obtained.

### CROSS-REFERENCES TO RELATED APPLICATIONS

This application claims the benefit of priority to Taiwanese Patent Application No. 112134972 filed on Sep. 13, 2023, which is hereby incorporated by reference in its entirety.

### BACKGROUND OF THE INVENTION

### Field of the Invention

The present invention relates to a porous silicon structure manufacturing method, and in particular to a porous silicon structure manufacturing method that can avoid wafer warpage and porous silicon cracks.

### Descriptions of the Related Art

Porous silicon is a material commonly used in semiconductor manufacturing and microfabrication. It has excellent thermal insulation and lightweight properties, so it is widely used in various electronic components and devices. However, there are some technical problems in the process of manufacturing porous silicon structures, such as the formation of wafer warpage and porous silicon cracks.

Electrochemical etching is one of the main steps in manufacturing porous silicon structures. However, over-etching will cause a problem of the wafer warpage, which is caused by uneven stress on the substrate during the etching process. In addition, insufficient etching depth will lead to poor thermal insulation effect of the porous silicon structure. This is a problem caused by the porous structure of the porous silicon not being fully formed.

In view of this, the present invention provides a porous silicon structure manufacturing method, which can ensure the accuracy and stability of the etching depth of the porous silicon structure, so as to greatly improve the production yield.

### SUMMARY OF THE INVENTION

The objective of the present invention is to provide a method for manufacturing a porous silicon structure by designing the resistance value of the epitaxial layer to be greater than or equal to 10 times the resistance value of the substrate, and monitoring the resistance of the protective layer during the electrochemical etching process. The side etching width is monitored and used to calculate the etching depth of the porous silicon structure during the electrochemical etching process. Then, the determination to halt electrochemical etching is based on the etching depth of the porous silicon structure. Therefore, the accuracy and stability of the etching depth of the porous silicon structure can be ensured, which not only avoids warpage of the wafer and cracks in the porous silicon structure, but also greatly improves the production yield.

To achieve the above objective, the present invention discloses a porous silicon structure manufacturing method. The method comprises the following steps: forming an epitaxial layer on a substrate; forming a protective layer on the epitaxial layer, wherein the protective layer includes an opening region; performing an electrochemical etching within the opening region to create a porous silicon structure on the epitaxial layer; and removing the protective layer.

In one embodiment of the present invention, when the electrochemical etching is performed, an etching rate of the epitaxial layer is greater than or equal to 10 times an etching rate of the substrate.

In one embodiment of the present invention, a resistance value of the epitaxial layer is greater than or equal to 10 times a resistance value of the substrate.

In one embodiment of the present invention, a thickness of the epitaxial layer ranges from 20 micrometers (μm) to 80 micrometers (μm).

In one embodiment of the present invention, the substrate is a silicon substrate.

In one embodiment of the present invention, the epitaxial layer is a P-type doped epitaxial layer.

In one embodiment of the present invention, a thickness of the protection layer ranges from 200 nanometers (nm) to 500 nanometers (nm).

In one embodiment of the present invention, the electrochemical etching is conducted to perform an anodic etching to the epitaxial layer by using an etching solution made of hydrofluoric acid (HF) and ethanol (C₂H₅OH).

In one embodiment of the present invention, the epitaxial layer includes a porous silicon region and a non-porous silicon region, and a thickness of the porous silicon region is the same as a thickness of the epitaxial layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 shows a cross-sectional view of the wafer before etching according to the present invention;

FIG. 2 shows a cross-sectional view of the wafer after etching according to the present invention; and

FIG. 3 shows a cross-sectional view of the wafer after etching and removal of the protective layer according to the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

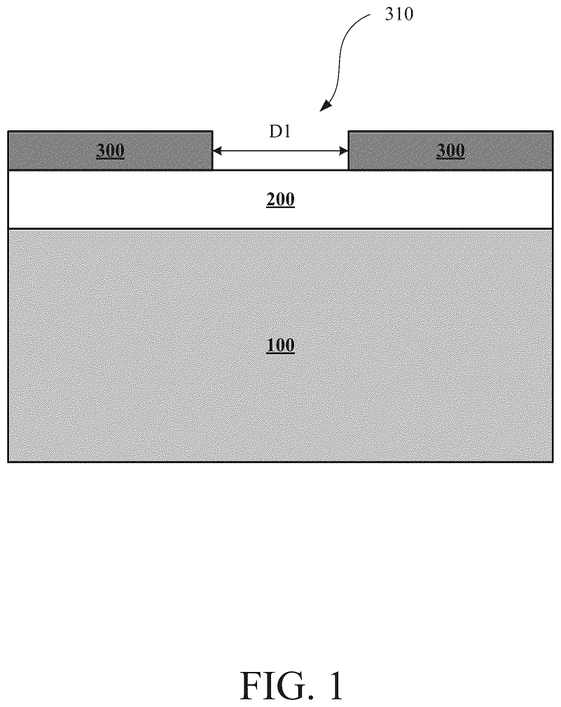

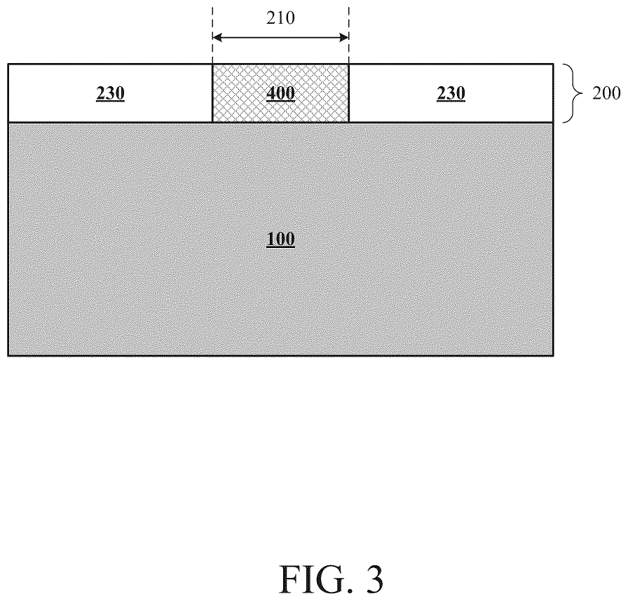

Please refer to FIG. 1 through FIG. 3, which depict the process of manufacturing a porous silicon (PS) structure at different stages. Firstly, an epitaxial layer 200 is formed on a substrate 100, and a protective layer 300 is formed on the epitaxial layer 200. The substrate 100 is a silicon substrate, and the epitaxial layer 200 is a P-type doped epitaxial layer.

In the present invention, to prevent wafer warpage and avoid cracks in the porous silicon structure, the resistance value of the epitaxial layer 200 needs to be greater than or equal to 10 times the resistance value of the substrate 100. Additionally, the thickness of the epitaxial layer 200 needs to range from 20 micrometers (μm) to 80 micrometers (μm), while the thickness of the substrate 100 is typically greater than or equal to 500 micrometers.

In other embodiments, the optimal resistance value of the epitaxial layer 200 is 10 to 15 times the resistance value of the substrate 100. Additionally, the optimal thickness of the epitaxial layer 200 ranges from 40 micrometers to 50 micrometers.

The thickness of the protective layer 300 typically ranges from 200 nanometers (nm) to 500 nanometers (nm). The protective layer 300 includes an opening region 310. An electrochemical etching is performed within the opening region 310 to create a porous silicon structure 400 in the epitaxial layer 200. The initial width D1 of the opening region 310 is the same as the width D5 of the porous silicon structure 400. The electrochemical etching is conducted to perform an anodic etching to the epitaxial layer 200 by using an etching solution made of hydrofluoric acid (HF) and ethanol (C₂H₅OH).

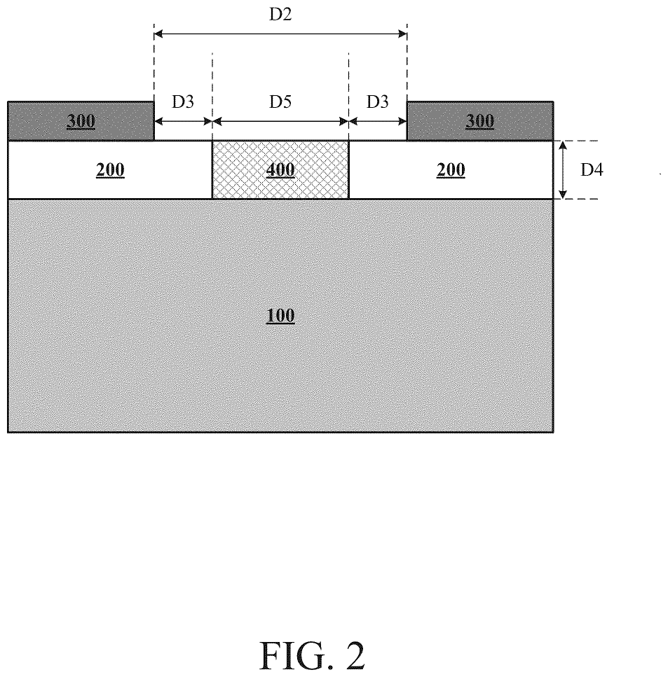

Please refer to both FIG. 1 and FIG. 2. The material of the protective layer 300 can be a silicon nitride dielectric layer. During the electrochemical etching process, the protective layer 300 will retract on both sides. Therefore, it is necessary to monitor the distance of the retraction of the protective layer 300 and calculate the etching depth of the porous silicon structure 400 based on the side etching width of the protective layer 300. The side etching width D3 of the protective layer 300 is equal to the etching depth D4 of the porous silicon structure. When the side etching width D3 reaches the required etching depth D4, the etching process is immediately stopped to ensure the accuracy and stability of the etching depth of the porous silicon structure 400.

In one embodiment, the etching depth D4 of the porous silicon structure 400 is the same as the thickness of the epitaxial layer 200. Specifically, the epitaxial layer 200 comprises a porous silicon region 210 and a non-porous silicon region 230. The porous silicon structure 400 is disposed in the porous silicon region, and the thickness of the porous silicon region is the same as the thickness of the epitaxial layer.

Since the protective layer 300 retracts during the electrochemical etching process, the after-etching width D2 of the opening region 310 is wider than the initial width D1 of the opening region 310. Additionally, during the electrochemical etching, the etching rate of the epitaxial layer 200 is greater than or equal to 10 times the etching rate of the substrate 100. In other words, when the electrochemical etching reaches the position of the substrate 100, the etching rate slows down with an effect of stopping the process.

Finally, after completing the electrochemical etching, the protective layer 300 is removed and a wafer with the porous silicon structure 200 can be obtained.

In summary, the method for manufacturing porous silicon structures of the present invention involves designing the resistance value of the P-type doped epitaxial layer to be at least 10 times greater than the resistance value of the P-type silicon substrate, and disposing a silicon nitride dielectric layer as a protective layer on the P-type doped epitaxial layer. The protective layer includes an opening region, which is the area for electrochemical etching. By monitoring the side etching width of the protective layer during the electrochemical etching process, the etching depth of the porous silicon structure is estimated, and the decision to stop the electrochemical etching is based on the etching depth of the porous silicon structure. Therefore, the accuracy and stability of the etching depth of the porous silicon structure are ensured, not only avoiding wafer warpage and cracks in the porous silicon structure but also significantly improving production yield.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A porous silicon structure manufacturing method, comprising:
forming an epitaxial layer on a substrate;
forming a protective layer on the epitaxial layer, wherein the protective layer includes an opening region;
performing an electrochemical etching within the opening region to create a porous silicon structure on the epitaxial layer; and
removing the protective layer.

2. The porous silicon structure manufacturing method of claim 1, wherein when the electrochemical etching is performed, an etching rate of the epitaxial layer is greater than or equal to 10 times an etching rate of the substrate.

3. The porous silicon structure manufacturing method of claim 1, wherein a resistance value of the epitaxial layer is greater than or equal to 10 times a resistance value of the substrate.

4. The porous silicon structure manufacturing method of claim 1, wherein a thickness of the epitaxial layer ranges from 20 micrometers (μm) to 80 micrometers (μm).

5. The porous silicon structure manufacturing method of claim 1, wherein the substrate is a silicon substrate.

6. The porous silicon structure manufacturing method of claim 1, wherein the epitaxial layer is a P-type doped epitaxial layer.

7. The porous silicon structure manufacturing method of claim 1, wherein a thickness of the protection layer ranges from 200 nanometers (nm) to 500 nanometers (nm).

8. The porous silicon structure manufacturing method of claim 1, wherein the electrochemical etching is conducted to perform an anodic etching to the epitaxial layer by using an etching solution made of hydrofluoric acid (HF) and ethanol (C₂H₅OH).

9. The porous silicon structure manufacturing method of claim 1, wherein the epitaxial layer includes a porous silicon region and a non-porous silicon region, and a thickness of the porous silicon region is the same as a thickness of the epitaxial layer.
